(19) United States
(12) Patent Application Publication
(10) Pub. No.: US 2025/0104901 A1
(43) Pub. Date: Mar. 27, 2025

(54) Integrated Transformer

(71) Applicant: AA Power Inc., Boston, MA (US)

(72) Inventor: Qun Lu, Lexington, MA (US)

(21) Appl. No.: 18/807,719

(22) Filed: Aug. 16, 2024

Related U.S. Application Data
(60) Provisional application No. 63/539,733, filed on Sep. 21, 2023.

(51) Int. Cl. H01F 27/28; H01F 27/22; H01F 27/29; H01F 41/04; H01F 41/066; H02M 7/00; H02M 7/21; H05K 7/20

(52) U.S. Cl. CPC H01F 27/2804; H01F 27/22; H01F 27/292; H01F 41/041; H01F 41/066; H02M 7/003; H02M 7/21; H05K 7/209; H01F 2027/2809; H01F 2027/2814

(57) ABSTRACT

An integrated transformer includes a first core comprising a first center leg, a first outer leg and a second outer leg over a first base, a first primary coil wound around the first center leg, a first multilayer PCB comprising a plurality of first inner windings, wherein the first multilayer PCB comprises a first connector and a second connector, a plurality of first electronic components disposed on the first multilayer PCB, a second multilayer PCB comprising a plurality of second inner windings, wherein the second multilayer PCB comprises a third connector and a fourth connector, a second primary coil wound around the second center leg, a plurality of second electronic components disposed on the second multilayer PCB, and a second core comprising a second center leg, a third outer leg and a fourth outer leg over a second base.

### CROSS-REFERENCE TO RELATED APPLICATIONS

This application claims the benefit of U.S. Provisional Application No. 63/539,733, filed on Sep. 21, 2023, entitled “Integrated Transformer,” which application is hereby incorporated herein by reference.

### TECHNICAL FIELD

The present invention relates to an integrated transformer structure, and in particular to a transformer structure in the field of switching mode power supplies.

### BACKGROUND

A power conversion system usually includes an ac/dc stage and a dc/dc stage connected in cascade between an ac utility line and a plurality of loads. The ac/dc stage converts the power from the ac utility line to an intermediate dc distribution bus. The dc/dc stage converts the voltage on the intermediate de distribution bus to a plurality of voltage levels for the plurality of loads. A conventional ac/dc stage may comprise a variety of EMI filters, a bridge rectifier formed by four diodes, a power factor correction circuit and an isolated dc/dc power converter. The dc/dc stage may comprise a plurality of isolated dc/dc converters. Isolated dc/dc converters can be implemented by using different power topologies, such as inductor-inductor-capacitor (LLC) resonant converters, flyback converters, forward converters, half bridge converters, full bridge converters and the like.

In the power conversion system, a transformer is employed to provide isolation between a primary side and a secondary side of an isolated power converter. In order to increase the power delivered from the primary side to the secondary side, a plurality of transformers may be employed. The plurality of transformers may be integrated into a single device known as an integrated magnetics structure. The use of the integrated magnetic structure improves performance along with a reduction in size and weight.

The integrated magnetics structure includes a pair of magnetic cores, a plurality of primary windings and a plurality of secondary windings. Each magnetic core includes two side pillars and one center pillar. The center pillar can be used to realize the windings of the transformer.

With the progress of electronic technology to pursue higher power density, higher efficiency, smaller size has become the development direction of power supply products. Transformers are the core components of power supplies. How to reduce the transformer size, and improve power density has become a technical problem to be overcome. The present disclosure addresses this need.

### SUMMARY

These and other problems are generally solved or circumvented, and technical advantages are generally achieved, by preferred embodiments of the present disclosure which provide an integrated transformer structure.

In accordance with an embodiment, a method comprises a first core comprising a first center leg, a first outer leg and a second outer leg over a first base, a first primary coil wound around the first center leg, a first multilayer PCB comprising a plurality of first inner windings, wherein the first multilayer PCB comprises a first connector and a second connector, a plurality of first electronic components disposed on the first multilayer PCB, and a second core comprising a second center leg, a third outer leg and a fourth outer leg over a second base.

In accordance with another embodiment, a system comprises a first core comprising a first center leg, a first outer leg and a second outer leg over a first base, a first primary coil wound around the first center leg, a first multilayer PCB comprising a plurality of first inner windings, wherein the first multilayer PCB comprises a first connector and a second connector, a plurality of first electronic components disposed on the first multilayer PCB, a second multilayer PCB comprising a plurality of second inner windings, wherein the second multilayer PCB comprises a third connector and a fourth connector, a second primary coil wound around the second center leg, a plurality of second electronic components disposed on the second multilayer PCB, and a second core comprising a second center leg, a third outer leg and a fourth outer leg over a second base.

In accordance with yet another embodiment, a method comprises winding a first primary coil around a first center leg of a first core comprising a first outer leg, the first center leg and a second outer leg over a first base, embedding a plurality of first inner windings in a first multilayer PCB comprising a first connector and a second connector, disposing a plurality of first electronic components on the first multilayer PCB, embedding a plurality of second inner windings in a second multilayer PCB comprising a third connector and a fourth connector, winding a second primary coil around a second center leg of a second core comprising a third outer leg, the second center leg and a fourth outer leg over a second base, and disposing a plurality of second electronic components on the second multilayer PCB.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a schematic diagram of a portion of a power supply in accordance with various embodiments of the present disclosure;

FIG. 2 illustrates a perspective view of an implementation of the integrated transformer in accordance with various embodiments of the present disclosure;

FIG. 3 illustrates an exploded view of the integrated transformer shown in FIG. 2 in accordance with various embodiments of the present disclosure;

FIG. 4 illustrates a perspective view of the multilayer PCB shown in FIG. 3 in accordance with various embodiments of the present disclosure;

FIG. 5 illustrates an exploded view of the multilayer PCB shown in FIG. 3 in accordance with various embodiments of the present disclosure;

FIG. 6 illustrates a cross section view of the multilayer PCB shown in FIG. 3 in accordance with various embodiments of the present disclosure;

FIG. 7 illustrates an implementation of the layout of the power switches and filter capacitors in accordance with various embodiments of the present disclosure;

FIG. 8 is a diagram illustrating an example assembly view of an integrated transformer having a heat dissipation cover structure in accordance with various embodiments of the present disclosure;

FIG. 9 is a diagram illustrating an example assembly view of an integrated transformer having a heat sink in accordance with various embodiments of the present disclosure; and

FIG. 10 illustrates a flow chart of a method for assembling an integrated transformer shown in FIG. 3 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to preferred embodiments in a specific context, namely an integrated transformer structure The disclosure may also be applied, however, to a variety of power conversion systems. Hereinafter, various embodiments will be explained in detail with reference to the accompanying drawings.

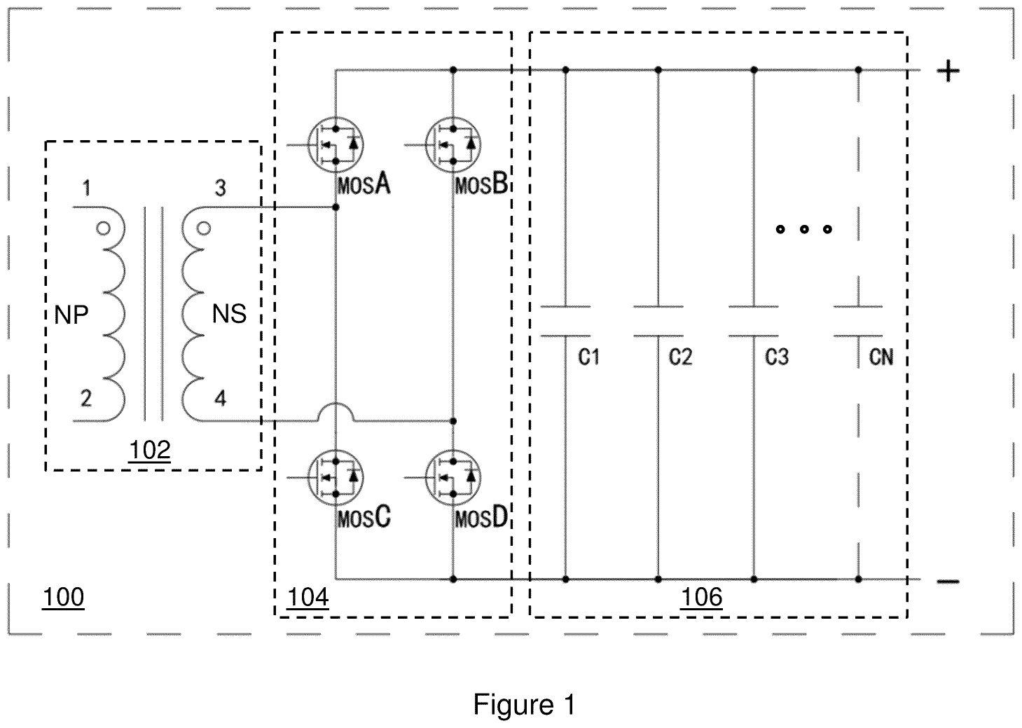

FIG. 1 illustrates a schematic diagram of a portion of a power supply in accordance with various embodiments of the present disclosure. The power supply 100 comprises a transformer 102, a rectifier 104 and a filter 106. In some embodiments, the power supply 100 is implemented as an isolated power converter (e.g., a full-bridge converter). The primary side circuit of the isolated power converter comprises a bridge switching circuit coupled to a first terminal (terminal 1 shown in FIG. 1) and a second terminal (terminal 2 shown in FIG. 1) of a primary winding NP of the transformer 102. The bridge switching circuit is well known, and hence is not discussed herein.

The secondary side circuit of the isolated power converter comprises a rectifier 104 and a filter 106 connected in cascade between the secondary winding NS of the transformer 102 and a load coupled to the output of the power supply 100. The rectifier 104 comprises a first switch MOSA, a second switch MOSB, a third switch MOSC and a fourth switch MOSD.

The first switch MOSA and the third switch MOSC are connected in series between a first output terminal and a second output terminal of the power supply 100. The second switch MOSB and the fourth switch MOSD are connected in series between the first output terminal and the second output terminal of the power supply 100. In some embodiments, the first output terminal of the power supply 100 is a positive output terminal. The second output terminal of the power supply 100 is connected to ground. Throughout the description, the first output terminal of the power supply 100 may be alternatively referred to as a positive output terminal of the power supply 100. The second output terminal of the power supply 100 may be alternatively referred to as a negative output terminal of the power supply 100.

As shown in FIG. 1, a common node of the first switch MOSA and the third switch MOSC is connected to a first terminal (terminal 3 shown in FIG. 1) of the secondary winding NS of the transformer 102 of the isolated power converter. A common node of the second switch MOSB and the fourth switch MOSD is connected to a second terminal (terminal 4 shown in FIG. 1) of the secondary winding NS of the transformer 102 of the isolated power converter. Depending on different applications and design needs, a secondary resonant capacitor may be connected in series with the secondary winding NS.

The filter 106 comprises a plurality of capacitors C1-CN connected in parallel between the positive output terminal and the negative terminal of the power supply 100. In alternative embodiments, the filter 106 may further comprise an output inductor connected between the rectifier 104 and the output capacitors C1-CN.

It should be noted that the diagram shown in FIG. 1 is merely an example, which should not unduly limit the scope of the claims. One of ordinary skill in the art would recognize many variations, alternatives, and modifications. For example, switches MOSA, MOSB, MOSC and MOSD may be replaced by diodes to simplify the control of the rectifier 104.

In accordance with an embodiment, the switches of FIG. 1 (e.g., switches MOSA, MOSB, MOSC and MOSD) may be metal oxide semiconductor field-effect transistor (MOSFET) devices, bipolar junction transistor (BJT) devices, super junction transistor (SJT) devices, insulated gate bipolar transistor (IGBT) devices, gallium nitride (GaN) based power devices and/or the like.

It should be noted while FIG. 1 shows the switches are implemented as single n-type transistors, a person skilled in the art would recognize there may be many variations, modifications and alternatives. For example, depending on different applications and design needs, at least some of the switches may be implemented as p-type transistors. Furthermore, each switch shown in FIG. 1 may be implemented as a plurality of switches connected in parallel. Moreover, a capacitor may be connected in parallel with one switch to achieve zero voltage switching (ZVS)/zero current switching (ZCS).

In some embodiments, the components shown in FIG. 1 are included in an integrated transformer structure. The integrated transformer structure comprises two magnetic cores (e.g., two PQ cores). The primary winding is implemented as an alpha type primary coil wound around center legs of the PQ cores. The secondary winding NS is implemented as copper traces routed in desired shapes in different layers of a multilayer printed circuit board (PCB). The multilayer PCB has a ring shape. The opening of the multilayer PCB is used to accommodate the center legs of the PQ cores. The rectifier 104 and the filter 106 are mounted on the multilayer PCB. As a result, the rectifier 104 and the filter 106 are placed inside the integrated transformer structure. Throughout the description, the integrated transformer structure may be alternatively referred to as an integrated transformer.

One advantageous feature of having the integrated transformer structure is that this integrated transformer structure reduces the size and weight of the power supply. Furthermore, the integrated transformer structure improves parasitic elements such as leakage inductance, interwinding capacitance. More particularly, the integrated transformer structure improves the electrical path from the transformer to the output MOS transistors and filter capacitors to minimize the AC and DC impedances, thereby improving power efficiency.

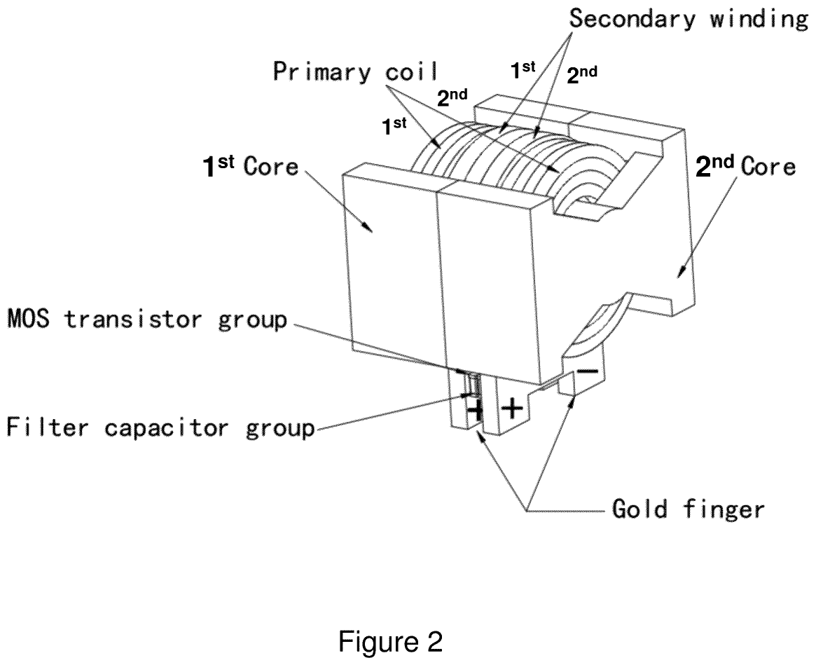

FIG. 2 illustrates a perspective view of an implementation of the integrated transformer in accordance with various embodiments of the present disclosure. The integrated transformer comprises a first core, a first primary coil, a first multilayer PCB, a plurality of first electronic components, a second multilayer PCB, a plurality of second electronic components, a second primary coil and a second core. In some embodiments, the plurality of first electronic components and the plurality of second electronic components comprise the switches of the rectifier 104 and the capacitors of the filter 106. As shown in FIG. 2, the switches of the rectifier 104 are labeled as a MOS transistor group. The capacitors of the filter 106 are labeled as a filter capacitor group.

In some embodiments, the first core and the second core are PQ cores. The first core comprises a base and three legs formed over or extending from the base. The three legs of the first core are a center leg, a first outer leg and a second outer leg of the first core. Likewise, the second core comprises a base and three legs formed over or extending from the base. The three legs of the second core are a center leg, a first outer leg and a second outer leg of the second core.

The primary winding shown in FIG. 1 is formed by two primary coils. A first primary coil is wound around the center leg of the first core. The first multilayer PCB comprises a plurality of first inner windings. The plurality of first inner windings is part of the secondary winding NS of the transformer 102. The first multilayer PCB comprises a first connector and a second connector. The first connector is a first gold-plated connector at an edge of the first multilayer PCB. This is also known as a first gold finger. The second connector is a second gold-plated connector at the edge of the first multilayer PCB. This is also known as a second gold finger.

A plurality of first electronic components is disposed on the first multilayer PCB. The plurality of first electronic components includes a first MOS transistor group (e.g., the switches shown in FIG. 1) and a first filter capacitor group (e.g., the capacitors shown in FIG. 1).

A second primary coil is wound around the center leg of the second core. The second multilayer PCB comprises a plurality of second inner windings. The plurality of second inner windings is part of the secondary winding NS of the transformer 102. The second multilayer PCB comprises a third connector and a fourth connector. The third connector is a third gold-plated connector at an edge of the second multilayer PCB. This is also known as a third gold finger. The fourth connector is a fourth gold-plated connector at the edge of the second multilayer PCB. This is also known as a fourth gold finger.

A plurality of second electronic components is disposed on the second multilayer PCB. The plurality of second electronic components includes a second MOS transistor group (e.g., the switches shown in FIG. 1) and a second filter capacitor group (e.g., the capacitors shown in FIG. 1).

The primary winding NP shown in FIG. 1 may be made by use of three-layer insulated wires or other insulated wires that are wound around. The primary winding NP may include two or more alpha type windings (also referred to as alpha type primary coils) connected in series, which can be flexible in providing a required number of turns, shorten the path of the series connection between the windings and ensure the flatness of the windings. The first primary coil and the second primary coil may be connected in parallel or in series, depending various applications.

As shown in FIG. 2, the first core and the second core are arranged side by side. The center leg of the first core faces toward the center leg of the second core. As shown in FIG. 2, the first primary coil is in direct contact with the base of the first core. The second primary coil is in direct contact with the base of the second core. The first multilayer PCB is in direct contact with the first primary coil. The second multilayer PCB is in direct contact with the second primary coil. The first multilayer PCB is in direct contact with the second multilayer PCB.

In some embodiments, at least one of the plurality of power switches (e.g., switches shown in FIG. 1) is directly driven by the secondary winding of the transformer (the plurality of first inner windings and/or the plurality of second inner windings). A gate of the at least one of the plurality of power switches is connected to the secondary winding of the transformer through a via or a plurality of vias.

In some embodiments, the first multilayer PCB further comprises a bias winding. The bias winding is connected to the plurality of first electronic components. The bias winding is configured to provide a gate drive signal for at least one power switch of the plurality of first electronic components.

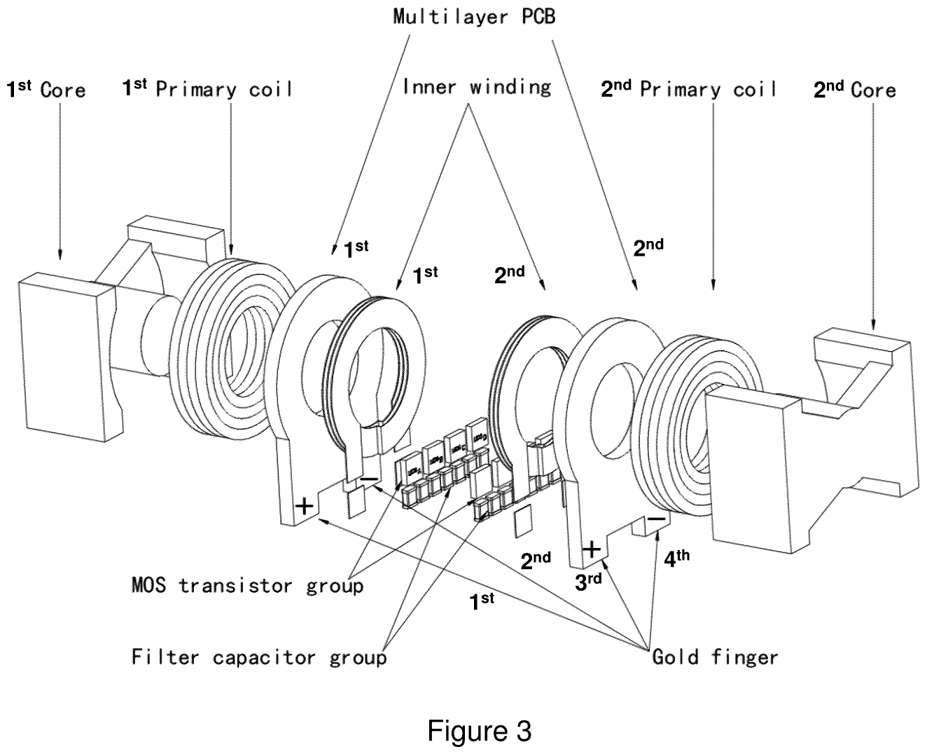

FIG. 3 illustrates an exploded view of the integrated transformer shown in FIG. 2 in accordance with various embodiments of the present disclosure. As shown in FIG. 3, the first multilayer PCB comprises a first main portion in a ring shape with a first opening. The first multilayer PCB further comprises a first connection portion, and a first connector and a second connector extending respectively from the connection portion. The first connector is a first gold-plated connector at an edge of the first multilayer PCB. The first connector is also known as a first gold finger. The second connector is a second gold-plated connector at the edge of the first multilayer PCB. The second connector is also known as a second gold finger. The first gold-plated connector serves as a first terminal (e.g., the positive terminal of the power supply) of the integrated transformer. The second gold-plated connector serves as a second terminal (e.g., the negative terminal of the power supply) of the integrated transformer.

As shown in FIG. 3, the second multilayer PCB comprises a second main portion in a ring shape with a second opening. The second multilayer PCB further comprises a second connection portion, and a third connector and a fourth connector extending respectively from the second main portion. The third connector is a third gold-plated connector at an edge of the second multilayer PCB. The third connector is also known as a third gold finger. The fourth connector is a fourth gold-plated connector at the edge of the second multilayer PCB. The fourth connector is also known as a fourth gold finger. The third gold-plated connector serves as a third terminal of the integrated transformer. The fourth gold-plated connector serves as a fourth terminal of the integrated transformer.

In some embodiments, the first gold-plated connector faces toward the third gold-plated connector. The first gold-plated connector is electrically connected to the third gold-plated connector. In some embodiments, the second gold-plated connector faces toward the fourth gold-plated connector. The second gold-plated connector is electrically connected to the fourth gold-plated connector.

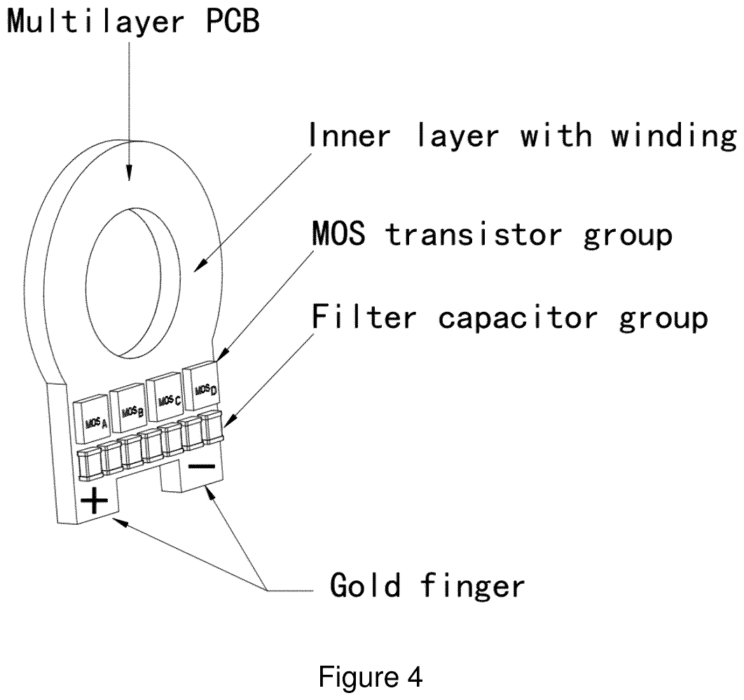

FIG. 4 illustrates a perspective view of the multilayer PCB shown in FIG. 3 in accordance with various embodiments of the present disclosure. The first multilayer PCB and the associated switches and capacitors are used as an example to illustrate how the switches and capacitors are mounted on the multilayer PCB.

The multiplayer PCB includes a main portion in a ring shape with an opening, a connection portion, a first gold finger and a second gold finger. The connection portion is rectangular in shape. As shown in FIG. 4, the connection portion is between the main portion and the gold fingers.

As shown in FIG. 4, the first switch MOSA, the second switch MOSB, the third switch MOSC and the fourth switch MOSD are placed in a first row adjacent to the opening of the multilayer PCB. The plurality of capacitors including C1-CN shown in FIG. 1 are placed in a second row adjacent to the first gold finger and the second gold finger of the multilayer PCB.

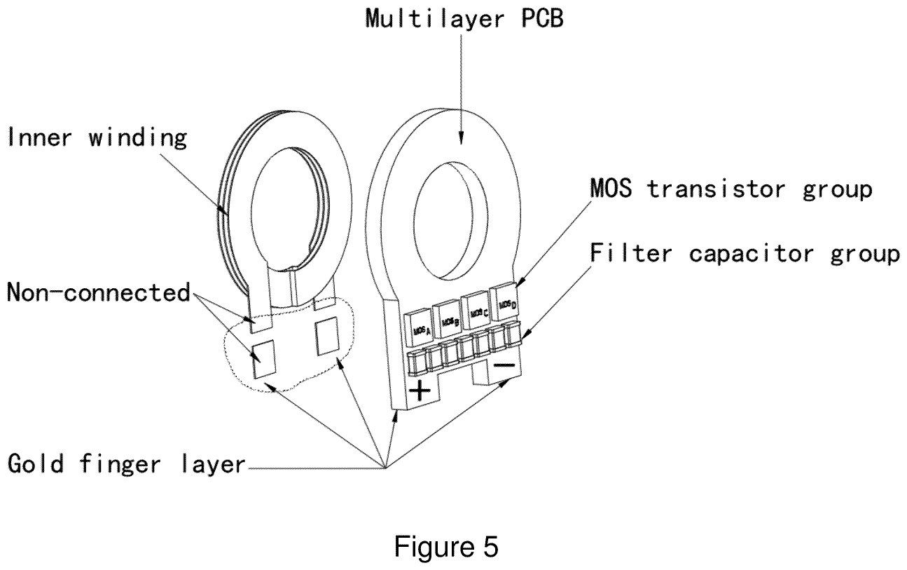

FIG. 5 illustrates an exploded view of the multilayer PCB shown in FIG. 3 in accordance with various embodiments of the present disclosure. The elements/components in FIG. 5 are basically similar to those described above with respect to FIG. 4, and hence are not discussed herein with further detail. Additionally, FIG. 5 shows the inner winding and connection pads (e.g., gold fingers shown in FIG. 5). As shown in FIG. 5, the inner winding is not connected to the connection pads. The inner winding is connected to the power switches through a plurality of first vias. The power switches are connected to the filter capacitors through various traces on or in the multilayer PCB. The filter capacitors are connected to the connection pads through a plurality of second vias.

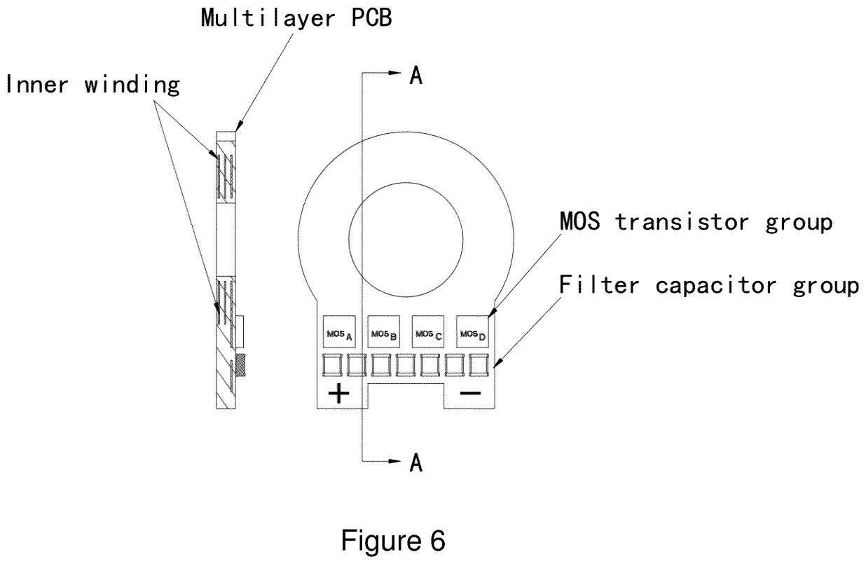

FIG. 6 illustrates a cross section view of the multilayer PCB shown in FIG. 3 in accordance with various embodiments of the present disclosure. The first multilayer PCB and the associated switches and capacitors are used as an example to illustrate how the switches and capacitors are mounted on the multilayer PCB.

The left side shows a cross sectional view of the multilayer PCB, the power switches and the filter capacitors along a line AA. The cross sectional view of the multilayer PCB shows the inner winding is placed in different layers of the multilayer PCB. The inner winding is not connected to the gold fingers.

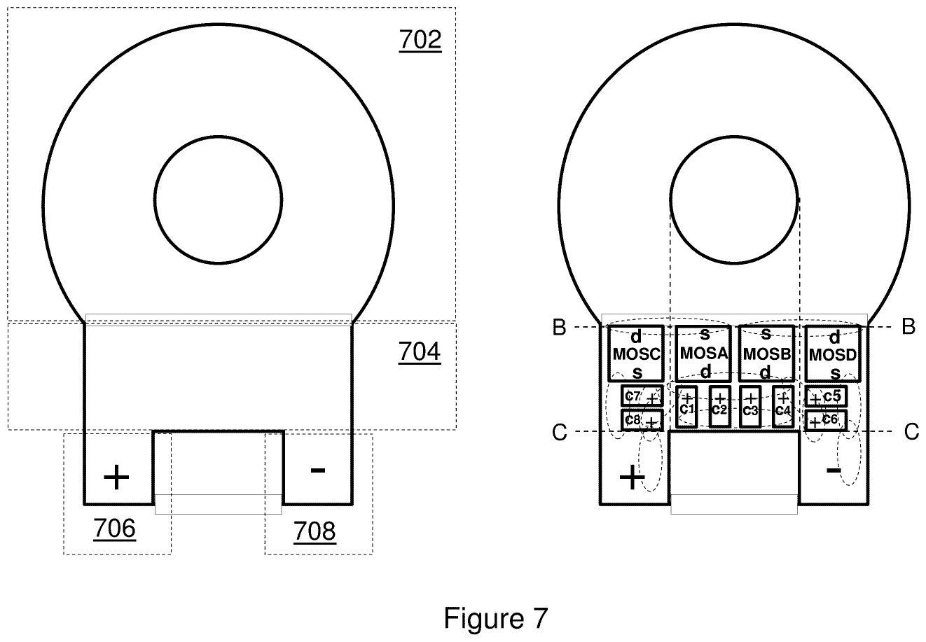

FIG. 7 illustrates an implementation of the layout of the power switches and filter capacitors in accordance with various embodiments of the present disclosure. The first multilayer PCB and the associated switches and filter capacitors shown in FIG. 3 are used as an example to illustrate how the switches and capacitors are mounted on the multilayer PCB.

The multilayer PCB includes four portions, namely a main portion 702, a connection portion 704, a first gold finger 706 and a second gold finger 708. As shown in FIG. 7, the main portion 702 has a ring shape having a center opening. The inner winding is formed inside the main portion 702. The connection portion 704 is rectangular in shape. The connection portion 704 is between the main portion 702 and the gold fingers 706, 708. Referring back to FIG. 1, the first gold finger 706 functions as a positive terminal of the power supply 100. The second gold finger 708 functions as a negative terminal of the power supply 100.

A line BB indicates the boundary between the main portion 702 and the connection portion 704. A line CC indicates the boundary between the connection portion 704 and the gold fingers. In some embodiments, the first switch MOSA, the second switch MOSB, the third switch MOSC and the fourth switch MOSD are implemented as n-type transistors. As shown in FIG. 7, the first switch MOSA, the second switch MOSB, the third switch MOSC and the fourth switch MOSD are placed in one row. The outmost edges of the drain of the third switch MOSC, the source of the first switch MOSA, the source of the second switch MOSB and the drain of the fourth switch MOSD are aligned with the BB line.

In some embodiments, the filter capacitors include eight capacitors. A first filter capacitor C1 and a second filter capacitor C2 are placed adjacent to the drain of the first switch MOSA. As shown in FIG. 7, a left side of the first filter capacitor C1 is vertically aligned with a left side of the first switch MOSA. A right side of the second filter capacitor C2 is vertically aligned with a right side of the first switch MOSA. A third filter capacitor C3 and a fourth filter capacitor C4 are placed adjacent to the drain of the second switch MOSB. As shown in FIG. 7, a left side of the third filter capacitor C3 is vertically aligned with a left side of the second switch MOSB. A right side of the fourth filter capacitor C4 is vertically aligned with a right side of the second switch MOSB.

A fifth filter capacitor C5 and a sixth filter capacitor C6 are placed adjacent to the fourth filter capacitor C4. The leftmost edges of C5 and C6 are vertically aligned with a leftmost edge of MOSD. A topmost edge of C5 is horizontally aligned with a topmost edge of C4. A bottommost edge of C6 is horizontally aligned with the line CC. A seventh filter capacitor C7 and an eighth filter capacitor C8 are placed adjacent to the first filter capacitor C1. The rightmost edges of C7 and C8 are vertically aligned with a rightmost edge of MOSC. A topmost edge of C7 is horizontally aligned with a topmost edge of C1. A bottommost edge of C8 is horizontally aligned with the line CC.

As indicated by the dashed oval overlapping the drain of MOSC and the source of MOSA, the drain of the third switch MOSC and the source of the first switch MOSA are connected together and further connected to a first terminal (terminal 3 of the secondary winding NS shown in FIG. 1) of the inner winding through suitable PCB connection structures (e.g., vias). Referring back to FIGS. 1 and 5, this layout configuration minimizes the connection length between the first terminal of the inner winding and the switches MOSA and MOSC.

As indicated by the dashed oval overlapping the drain of MOSD and the source of MOSB, the drain of the fourth switch MOSD and the source of the second switch MOSB are connected together and further connected to a second terminal (terminal 4 of the secondary winding NS shown in FIG. 1) of the inner winding through suitable PCB connection structures (e.g., vias). Referring back to FIGS. 1 and 5, this layout configuration minimizes the connection length between the second terminal of the inner winding and the switches MOSB and MOSD.

As indicated by the dashed oval overlapping the drain of MOSA, the drain of MOSB and the positive terminals of C₁-C₄, the drain of the first switch MOSA and the drain of the second switch MOSB are connected together and further connected to the positive terminals of C₁-C₄. Referring back to FIGS. 1 and 5, this layout configuration minimizes the connection length between the drains of MOSA, MOSB and the positive terminals of C₁-C₄. Furthermore, the positive terminals of C5 and C6 are adjacent to the positive terminal of C4. The positive terminals of C7 and C8 are adjacent to the positive terminal of C1. As indicated by the dashed ovals overlapping the drain of MOSA, the drain of MOSB and the positive terminals of C1-C8, the drain of the first switch MOSA, the drain of the second switch MOSB and the positive terminals of C1-C8 are connected together and further connected to the positive terminal of the power supply 100. Referring back to FIGS. 1 and 5, this layout configuration minimizes the connection length between the drains of MOSA, MOSB, the positive terminals of C₁-C₆ and the positive output terminal of the power supply 100.

As indicated by the dashed oval overlapping the source of MOSD and the negative terminals of C5-C6, the source of the fourth switch MOSD and the negative terminals of C5-C6 are connected together and further connected to the negative output terminal of the power supply 100. Referring back to FIGS. 1 and 5, this layout configuration minimizes the connection length between the source of MOSD and the negative terminal of the power supply 100. Furthermore, as indicated by the dashed oval overlapping the source of MOSC and the negative terminals of C7-C8, the source of the third switch MOSC and the negative terminals of C7-C8 are connected together and further connected to the negative output terminal of the power supply 100 through a suitable PCB connection structure (e.g., a ground plane embedded in the PCB). Moreover, as indicated by the dashed oval overlapping the negative terminals of C₁-C₄, the negative terminals of C7-C8 are connected together and further connected to the negative output terminal of the power supply 100 through a suitable PCB connection structure (e.g., a ground plane embedded in the PCB).

One advantageous feature of having the layout configuration shown in FIG. 7 is that the arrangement of the switches and filter capacitors helps to reduce parasitic inductance and connection resistance, thereby improving the efficiency of the power supply 100.

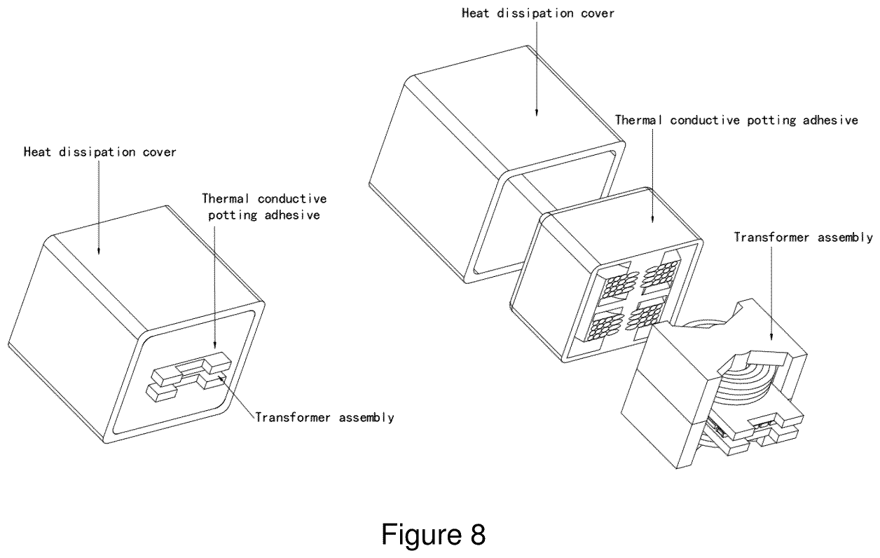

FIG. 8 is a diagram illustrating an example assembly view of an integrated transformer having a heat dissipation cover structure in accordance with various embodiments of the present disclosure. A heat dissipation cover structure is employed to further improve the thermal performance of the integrated transformer. As shown in FIG. 8, the first core, the second core, the first primary coil, the plurality of first inner windings, the plurality of first electronic components, the second primary coil, the plurality of second inner windings and the plurality of second electronic components are placed inside the heat dissipation cover structure. A thermal conductive potting adhesive material is configured to fill the heat dissipation cover structure. After the thermal conductive potting adhesive material has filled the heat dissipation cover structure, the integrated transformer becomes a module.

The module shown in FIG. 8 offers several advantages. Frist, the thermal conductive potting adhesive material enhances heat dissipation, helping to maintain operating temperatures and improve the longevity of the integrated transformer. Second, the thermal conductive potting adhesive material provides a sealed barrier that protects power switches and capacitors from environmental contaminants, increasing the reliability of the integrated transformer. Third, the thermal conductive potting adhesive material reduces the impact of vibrations and shocks, thereby helping the integrated transformer operating in harsh environments.

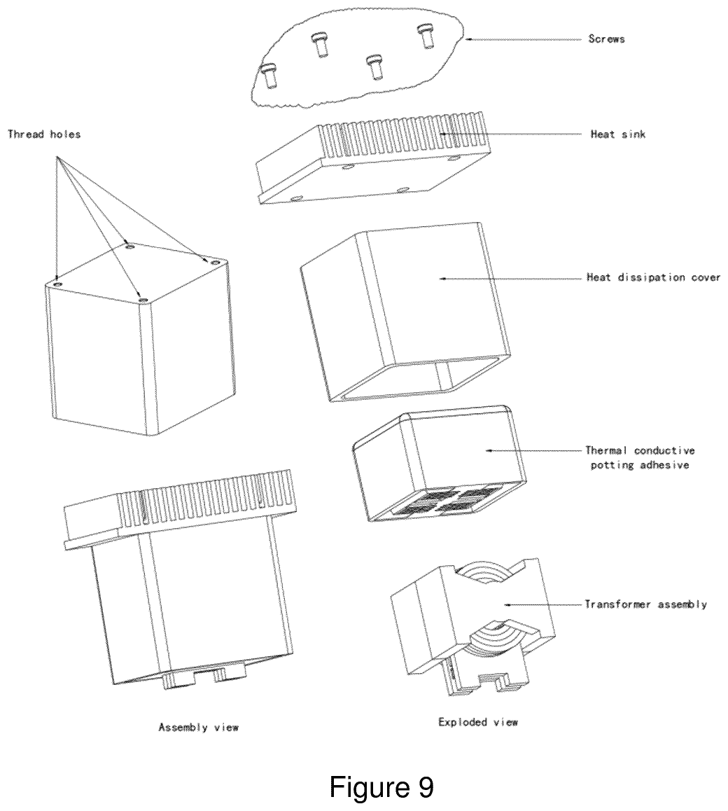

FIG. 9 is a diagram illustrating an example assembly view of an integrated transformer having a heat sink in accordance with various embodiments of the present disclosure. The elements/components in FIG. 9 are basically similar to those described above with respect to FIG. 8 except that a heat sink is mounted over the heat dissipation cover structure.

The heat sink has four through holes. The heat dissipation cover structure has four screw holes. The heat sink is mounted over the heat dissipation cover structure using four screws as shown in FIG. 9.

One advantageous feature of having the heat sink shown in FIG. 8 is the heatsink significantly improves the ability to dissipate heat, maintaining lower operating temperatures and preventing overheating, which can prolong the life of the integrated transformer.

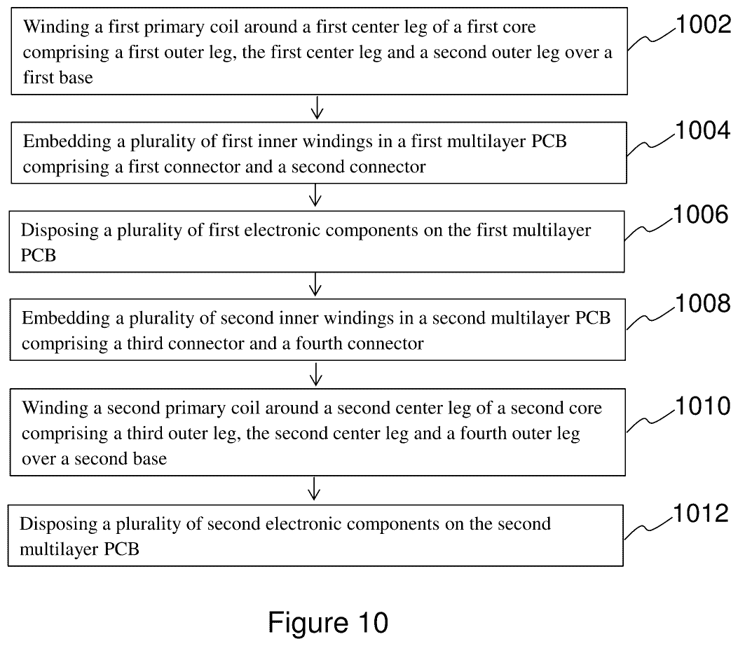

FIG. 10 illustrates a flow chart of a method for assembling an integrated transformer shown in FIG. 3 in accordance with various embodiments of the present disclosure. This flowchart shown in FIG. 10 is merely an example, which should not unduly limit the scope of the claims. One of ordinary skill in the art would recognize many variations, alternatives, and modifications. For example, various steps illustrated in FIG. 10 may be added, removed, replaced, rearranged and repeated.

FIG. 3 shows the integrated transformer comprises a first core, a first primary coil, a first multilayer PCB, a plurality of first electronic components, a second multilayer PCB, a plurality of second electronic components, a second primary coil and a second core. The plurality of first electronic components and the plurality of second electronic components comprises a plurality of switches (e.g., MOSA, MOSB, MOSC and MOSD shown in FIG. 1) and a plurality of filter capacitors (e.g., C1-CN shown in FIG. 1). The switches form a MOS transistor group as shown in FIG. 3. The filter capacitors form a filter capacitor group as shown in FIG. 3.

At step 1002, a first primary coil is wound around a first center leg of a first core comprising a first outer leg, the first center leg and a second outer leg over a first base.

At step 1004, a plurality of first inner windings is embedded in a first multilayer PCB comprising a first connector and a second connector.

At step 1006, a plurality of first electronic components is disposed on the first multilayer PCB.

At step 1008, a plurality of second inner windings is embedded in a second multilayer PCB comprising a third connector and a fourth connector.

At step 1010, a second primary coil is wound around a second center leg of a second core comprising a third outer leg, the second center leg and a fourth outer leg over a second base.

At step 1012, a plurality of second electronic components is disposed on the second multilayer PCB.

The method further comprises placing the first core, the second core, the first primary coil, the plurality of first inner windings, the plurality of first electronic components, the second primary coil, the plurality of second inner windings and the plurality of second electronic components inside a heat dissipation cover structure, and filling a thermal conductive potting adhesive material into the heat dissipation cover structure.

The method further comprises mounting a heat sink over the heat dissipation cover structure.

The plurality of first electronic components comprises a first switch, a second switch, a third switch, a fourth switch, a first capacitor, a second capacitor, a third capacitor, a fourth capacitor, a fifth capacitor, a sixth capacitor, a seventh capacitor and an eighth capacitor, and wherein the first switch and the third switch are connected in series between a first output terminal and a second output terminal of a power supply, and wherein a common node of the first switch and the third switch is connected to a first terminal of the plurality of first inner windings, the second switch and the fourth switch are connected in series between the first output terminal and the second output terminal of the power supply, and wherein a common node of the second switch and the fourth switch is connected to a second terminal of the plurality of first inner windings, and the first capacitor, the second capacitor, the third capacitor, the fourth capacitor, the fifth capacitor, the sixth capacitor, the seventh capacitor and the eighth capacitor are connected in parallel between the first output terminal and the second output terminal of the power supply.

The method further comprises disposing the first switch, the second switch, the third switch and the fourth switch in one row on the first multilayer PCB, wherein a drain of the third switch is adjacent to a source of the first switch, and a source of the second switch is adjacent to a drain of the fourth switch, disposing the first capacitor and the second capacitor adjacent to a drain of the first switch, wherein a leftmost edge of the first capacitor is aligned with a leftmost edge of the first switch, and a rightmost edge of the second capacitor is aligned with a rightmost edge of the first switch, disposing the third capacitor and the fourth capacitor adjacent to a drain of the second switch, wherein a leftmost edge of the third capacitor is aligned with a leftmost edge of the second switch, and a rightmost edge of the fourth capacitor is aligned with a rightmost edge of the second switch, disposing the fifth capacitor and the sixth capacitor adjacent to a source of the fourth switch, wherein a leftmost edge of the fifth capacitor is aligned with a leftmost edge of the fourth switch, and a leftmost edge of the sixth capacitor is aligned with the leftmost edge of the fourth switch, and disposing the seventh capacitor and the eighth capacitor adjacent to a source of the third switch, wherein a rightmost edge of the seventh capacitor is aligned with a rightmost edge of the third switch, and a rightmost edge of the eighth capacitor is aligned with the rightmost edge of the third switch.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus comprising:
a first core comprising a first center leg, a first outer leg and a second outer leg over a first base;
a first primary coil wound around the first center leg;
a first multilayer printed circuit board (PCB) comprising a plurality of first inner windings, wherein the first multilayer PCB comprises a first connector and a second connector;
a plurality of first electronic components disposed on the first multilayer PCB; and
a second core comprising a second center leg, a third outer leg and a fourth outer leg over a second base.

2. The apparatus of claim 1, wherein:
the first multilayer PCB comprising a first connection portion and a first main portion in a ring shape with a first opening, and wherein the first connector and the second connector extend respectively from the first connection portion, and wherein:
the first connector is a first gold-plated connector at an edge of the first multilayer PCB, and the first gold-plated connector serves as a first terminal of the apparatus; and
the second connector is a second gold-plated connector at the edge of the first multilayer PCB, and the second gold-plated connector serves as a second terminal of the apparatus.

3. The apparatus of claim 1, wherein:
the first core and the second core are arranged side by side, and wherein the first center leg of the first core faces toward the second center leg of the second core.

4. The apparatus of claim 3, further comprising:
a second multilayer PCB comprising a plurality of second inner windings, wherein the second multilayer PCB comprises a third connector and a fourth connector;
a second primary coil wound around the second center leg; and
a plurality of second electronic components disposed on the second multilayer PCB.

5. The apparatus of claim 4, wherein:
the second multilayer PCB comprises a second connection portion and a second main portion in a ring shape with a second opening, and wherein the third connector and the fourth connector extend respectively from the second connection portion.

6. The apparatus of claim 4, wherein:
the first primary coil is in direct contact with the first base of the first core;
the second primary coil is in direct contact with the second base of the second core;
the first multilayer PCB is in direct contact with the first primary coil;
the second multilayer PCB is in direct contact with the second primary coil; and
the first multilayer PCB is in direct contact with the second multilayer PCB.

7. The apparatus of claim 1, wherein:
the plurality of first electronic components comprises a plurality of power switches and a plurality of capacitors.

8. The apparatus of claim 7, wherein:
the plurality of power switches and the plurality of capacitors form a secondary side circuit of a full-bridge converter, and wherein the secondary side circuit comprises a rectifier and a filter connected in cascade between a secondary winding of a transformer of the full-bridge converter and an output of the full-bridge converter, and wherein at least one of the plurality of power switches is directly driven by the plurality of first inner windings, and a gate of the at least one of the plurality of power switches is connected to the plurality of first inner windings through a via.

9. The apparatus of claim 8, wherein:
the filter comprises a plurality of ceramic capacitors connected in parallel; and
the rectifier comprises a first switch, a second switch, a third switch and a fourth switch, and wherein:
the first switch and the second switch are connected in series between a first output terminal and a second output terminal of the full-bridge converter, and wherein a common node of the first switch and the second switch is connected to a first terminal of the secondary winding; and
the third switch and the fourth switch are connected in series between the first output terminal and the second output terminal of the full-bridge converter, and wherein a common node of the third switch and the fourth switch is connected to a second terminal of the secondary winding; and
the plurality of capacitors is connected in parallel between the first output terminal and the second output terminal of the full-bridge converter.

10. The apparatus of claim 9, wherein:
the first switch, the second switch, the third switch and the fourth switch are placed in a first row adjacent to a first opening of the first multilayer PCB; and
the plurality of capacitors are placed in a second row adjacent to the first connector and the second connector of the first multilayer PCB.

11. The apparatus of claim 1, wherein:
the first primary coil is an alpha type primary coil; and
the first multilayer PCB further comprises a bias winding, and wherein the bias winding is connected to the plurality of first electronic components, and the bias winding is configured to provide a gate drive signal for at least one power switch of the plurality of first electronic components.

12. The apparatus of claim 1, further comprising:
a heat dissipation cover structure, wherein the first core, the second core, the first primary coil, the plurality of first inner windings and the plurality of first electronic components are placed inside the heat dissipation cover structure;
a thermal conductive potting adhesive material configured to fill the heat dissipation cover structure; and
a heat sink over the heat dissipation cover structure.

13. A system comprising:
a first core comprising a first center leg, a first outer leg and a second outer leg over a first base;
a first primary coil wound around the first center leg;
a first multilayer PCB comprising a plurality of first inner windings, wherein the first multilayer PCB comprises a first connector and a second connector;
a plurality of first electronic components disposed on the first multilayer PCB;
a second multilayer PCB comprising a plurality of second inner windings, wherein the second multilayer PCB comprises a third connector and a fourth connector;
a second primary coil wound around the second center leg;
a plurality of second electronic components disposed on the second multilayer PCB; and
a second core comprising a second center leg, a third outer leg and a fourth outer leg over a second base.

14. The system of claim 13, wherein:
the plurality of first electronic components comprises a plurality of first power switches and a plurality of first capacitors; and
the plurality of second electronic components comprises a plurality of second power switches and a plurality of second capacitors, and wherein;
the plurality of first power switches and the plurality of second power switches form a rectifier; and
the plurality of first capacitors and the plurality of second capacitors form a filter.

15. The system of claim 13, wherein:
the plurality of first power switches, the plurality of first capacitors, the plurality of second power switches and the plurality of second capacitors form a secondary side circuit of a full-bridge converter, and wherein the secondary side circuit comprises a rectifier and a filter connected in cascade between a secondary winding of a transformer of the full-bridge converter and an output of the full-bridge converter.

16. A method comprising:
winding a first primary coil around a first center leg of a first core comprising a first outer leg, the first center leg and a second outer leg over a first base;
embedding a plurality of first inner windings in a first multilayer PCB comprising a first connector and a second connector;
disposing a plurality of first electronic components on the first multilayer PCB;
embedding a plurality of second inner windings in a second multilayer PCB comprising a third connector and a fourth connector;
winding a second primary coil around a second center leg of a second core comprising a third outer leg, the second center leg and a fourth outer leg over a second base; and
disposing a plurality of second electronic components on the second multilayer PCB.

17. The method of claim 16, further comprising:
placing the first core, the second core, the first primary coil, the plurality of first inner windings, the plurality of first electronic components, the second primary coil, the plurality of second inner windings and the plurality of second electronic components inside a heat dissipation cover structure; and
filling a thermal conductive potting adhesive material into the heat dissipation cover structure.

18. The method of claim 17, further comprising:
mounting a heat sink over the heat dissipation cover structure.

19. The method of claim 16, wherein:
the plurality of first electronic components comprises a first switch, a second switch, a third switch, a fourth switch, a first capacitor, a second capacitor, a third capacitor, a fourth capacitor, a fifth capacitor, a sixth capacitor, a seventh capacitor and an eighth capacitor, and wherein:
the first switch and the third switch are connected in series between a first output terminal and a second output terminal of a power supply, and wherein a common node of the first switch and the third switch is connected to a first terminal of the plurality of first inner windings;
the second switch and the fourth switch are connected in series between the first output terminal and the second output terminal of the power supply, and wherein a common node of the second switch and the fourth switch is connected to a second terminal of the plurality of first inner windings; and
the first capacitor, the second capacitor, the third capacitor, the fourth capacitor, the fifth capacitor, the sixth capacitor, the seventh capacitor and the eighth capacitor are connected in parallel between the first output terminal and the second output terminal of the power supply.

20. The method of claim 19, further comprising:
disposing the first switch, the second switch, the third switch and the fourth switch in one row on the first multilayer PCB, wherein a drain of the third switch is adjacent to a source of the first switch, and a source of the second switch is adjacent to a drain of the fourth switch;
disposing the first capacitor and the second capacitor adjacent to a drain of the first switch, wherein a leftmost edge of the first capacitor is aligned with a leftmost edge of the first switch, and a rightmost edge of the second capacitor is aligned with a rightmost edge of the first switch;
disposing the third capacitor and the fourth capacitor adjacent to a drain of the second switch, wherein a leftmost edge of the third capacitor is aligned with a leftmost edge of the second switch, and a rightmost edge of the fourth capacitor is aligned with a rightmost edge of the second switch;
disposing the fifth capacitor and the sixth capacitor adjacent to a source of the fourth switch, wherein a leftmost edge of the fifth capacitor is aligned with a leftmost edge of the fourth switch, and a leftmost edge of the sixth capacitor is aligned with the leftmost edge of the fourth switch; and
disposing the seventh capacitor and the eighth capacitor adjacent to a source of the third switch, wherein a rightmost edge of the seventh capacitor is aligned with a rightmost edge of the third switch, and a rightmost edge of the eighth capacitor is aligned with the rightmost edge of the third switch.
